(19) United States
(12) Patent Application Publication
(10) Pub. No.: US 2022/0357383 A1
(43) Pub. Date: Nov. 10, 2022

(54) IDENTIFYING ELECTRICAL PHASES OF ELECTRIC GRID WIRES

(71) Applicant: X Development LLC, Mountain View, CA (US)

(72) Inventors: Phillip Ellsworth Stahlfeld, Mountain View, CA (US); Ananya Gupta, San Francisco, CA (US)

(21) Appl. No.: 17/729,627

(22) Filed: Apr. 26, 2022

Related U.S. Application Data
(60) Provisional application No. 63/185,403, filed on May 7, 2021.

(51) Int. Cl. G01R 29/18; G06V 10/44; G06T 7/70

(52) U.S. Cl. CPC G01R 29/18; G06V 10/44; G06T 7/70

(57) ABSTRACT

Methods, systems, and apparatus, including computer programs encoded on a storage device, for identifying phases of electrical grid wires are disclosed. A method includes identifying, within an image of a utility pole, a cross-arm supporting multiple wires; identifying a cardinal orientation of the cross-arm based on characteristics of the image; and determining, based on the cardinal orientation of the cross-arm, an electrical phase for each of the wires supported by the cross-arm. Identifying the cardinal orientation of the cross-arm includes: determining an orientation of the cross-arm relative to an axis of a field of view of the image; determining a cardinal orientation of the axis of the field of view; and estimating the cardinal orientation of the cross-arm based on an angular difference between the orientation of the cross-arm relative to the axis of a field of view and the cardinal orientation of the axis of the field of view.

### CROSS-REFERENCE TO RELATED APPLICATION

This application claims the benefit of U.S. Provisional Patent Application No. 63/185,403, filed May 7, 2021, the contents of which are incorporated by reference herein.

### TECHNICAL FIELD

The present specification relates to electric power grids, and specifically to identifying phases of power lines of electric power grids.

### BACKGROUND

Electric generating power plants commonly produce three phase alternating current (AC) electrical power. The voltage of the transmitted and distributed electric power can be increased or reduced by transformers located at substations or switching yards, or on feeders located between power plants and loads. The three-phase power can be distributed through an electrical grid to provide power to loads such as residential, commercial, and industrial properties. Residential homes and small businesses are typically fed from one phase of an electrical distribution system. For efficient electric grid operations, load should be balanced across the three phases. Phase imbalances can occur over time as loads are moved or new loads assigned. Load imbalance can have negative effects, particularly on the efficiency of three-phase transformers. Although the phase information is incredibly useful for running a grid, often the phase assignments of loads are not well documented.

### SUMMARY

In general, the present disclosure relates to a system for identifying electrical phases of electric grid wires using camera images. Electrical loads, such as residential properties and small businesses are often connected to one phase of a three-phase electrical grid. A three-phase electrical distribution system is most efficient when the loads on each phase are equally balanced. If loads are not connected in a balanced manner, the loads can cause phase imbalances in the electric grid, thereby decreasing electric grid efficiency.

To aid in balancing loads on an electrical distribution system, the phase of existing loads can be identified. A phase identification system can employ street level imagery to identify an alternating current (AC) phase of each grid wire supported by a utility pole. The street level imagery data can be collected and stored along with data indicating locations of the sensors that collected the imagery data. The data can also be stored along with data indicating locations of the utility poles in the imagery.

The phase identification system can also detect and classify electric grid assets located on or near the utility pole, and identify an electrical phase to which each asset is connected. Once the phases of existing loads are identified, phase balancing can be improved by realigning the phases of existing loads, by planning the phase of alignment of future loads, or both.

In general, innovative aspects of the subject matter described in this specification can be embodied in an electrical phase detection method including: identifying, within an image of a utility pole, a cross-arm supporting multiple wires; identifying a cardinal orientation of the cross-arm based on characteristics of the image; and determining, based on the cardinal orientation of the cross-arm, an electrical phase for each of the multiple wires supported by the cross-arm.

These and other embodiments can include the following features, alone or in any combination. In some implementations, identifying the cross-arm supporting multiple wires includes: processing the image with an object detection model to obtain a corresponding output of the object detection model, the corresponding output of the object detection model including a bounding box around the cross-arm in the image.

In some implementations, identifying the cardinal orientation of the cross-arm includes: determining an orientation of the cross-arm relative to an axis of a field of view of the image; determining, based on the characteristics of the image, a cardinal orientation of the axis of the field of view; and estimating the cardinal orientation of the cross-arm based on an angular difference between the orientation of the cross-arm relative to the axis of a field of view and the cardinal orientation of the axis of the field of view.

In some implementations, determining the orientation of the cross-arm relative to the axis of the field of view of the image includes determining an aspect ratio of the bounding box around the cross-arm in the image, the aspect ratio indicating the orientation of the cross-arm relative to the axis of a field of view.

In some implementations, identifying the cardinal orientation of the cross-arm includes: identifying a cardinal orientation of a street adjacent to the utility pole within a map of a geographic location of the utility pole; and determining the cardinal orientation of the cross-arm based on the cardinal orientation of the street.

In some implementations, the cardinal orientation of the cross-arm is approximately orthogonal to the cardinal orientation of the street.

In some implementations, determining the electrical phase for each of the multiple wires includes: identifying, for each wire, a respective position of the wire on the cross-arm; and determining, for each wire, a respective electrical phase of the wire based on the respective position of the wire on the cross-arm and the cardinal orientation of the cross-arm.

In some implementations, the respective electrical phase of the wire is determined based on the respective position of the wire on the cross-arm and the cardinal orientation of the cross-arm as compared with a wire phasing diagram.

In some implementations, the respective electrical phase of the wire is determined based on the respective position of the wire on the cross-arm and the cardinal orientation of the cross-arm as compared with a wire phasing map.

In some implementations, the method further includes: identifying, within the image, a transformer and a stirrup; and determining a particular electrical phase to which the transformer is connected by identifying a particular wire of the multiple wires that is nearest to the stirrup.

In some implementations, the image of the utility pole includes a depiction of an electric grid asset, the electric grid asset including one of a capacitor, a fuse, a transformer, or a switch.

In some implementations, the method further includes: identifying, within the image, the electric grid asset; and determining a particular electrical phase to which the electric grid asset is connected by identifying, within the image, a particular wire of the multiple wires that is connected to the electric grid asset.

In some implementations, the method further includes: determining a particular electrical phase to which the electric grid asset is connected, the determining including: processing the image with a convolutional neural network model to obtain a corresponding output of the convolutional neural network model, the corresponding output of the convolutional neural network model including a classification of the electric grid asset as being connected to a particular wire of the multiple wires.

In some implementations, the image includes at least one of visible light imagery, infrared imagery, hyperspectral imagery, multispectral imagery, RADAR imagery, or LIDAR imagery.

In some implementations, the image of the utility pole includes a camera image captured by a camera positioned at street level.

In some implementations, the characteristics of the image include one or more of: metadata indicating an orientation of a camera at a time the image was captured, LIDAR data associated with the image, or geographic location data associated with the image.

The subject matter described in this specification can be implemented in various embodiments and may result in one or more of the following technical advantages. The disclosed processes can be used to improve the overall efficiency of electrical power systems, e.g., power transmission and distribution systems. For example, an identification system can identify a particular phase of a multi-phase electrical power distribution system to aid in balancing loads. Knowing the phase to which a particular transformer is connected is useful for grid operations and planning because the phase information can be used to determine how loads are distributed across phases of the electric grid. The disclosed techniques provide for non-intrusive phase identification in electrical power systems, and do not require any physical electrical connections. Phases of electrical grid wires and transformers can thus be determined without making physical contact with the grid wires, improving safety of personnel and equipment.

Other implementations of the above aspects include corresponding systems, apparatus, and computer programs configured to perform the actions of the methods, encoded on computer storage devices. The details of one or more implementations of the subject matter described in this specification are set forth in the accompanying drawings and the description below. Other features, aspects, and advantages of the subject matter will become apparent from the description, the drawings, and the claims.

### DESCRIPTION OF DRAWINGS

FIG. 1 is a diagram of an example system for identifying electrical phases of electric grid wires using camera images.

FIG. 2 illustrates an example street level image of a utility pole.

FIG. 3 illustrates an example overhead view of a portion of an electrical grid.

FIG. 4 is a flow diagram of an example process for identifying electrical phases of electric grid wires using camera images.

Like reference numbers and designations in the various drawings indicate like elements.

### DETAILED DESCRIPTION

This disclosure generally describes computer-implemented methods, software, and systems for identifying electrical phases of electric grid wires using camera images. Specifically, the present disclosure provides a system and method to assign an electrical phase to grid wires of an electric grid and to other components of the electric grid, such as transformers. The phase identification system can determine that a particular transformer of the electric grid is fed from phase “A,” “B,” or “C” of the electrical distribution system.

Implementations of the present disclosure will be discussed in further detail with reference to an example context, however, it should be appreciated that the implementations disclosed may be applicable more generally to any electric grid component that is connected to a phase of an electrical grid. The example context includes a single transformer mounted to a utility pole. The utility pole is a component of an electrical distribution system that distributes three phase alternating current (AC) power to loads. It is also appreciated, however, that implementations of the present disclosure can be realized in other appropriate contexts, for example, identifying electrical phases of a single transformer located near a utility pole, or identifying electrical phases of two or more transformers mounted to a utility pole.

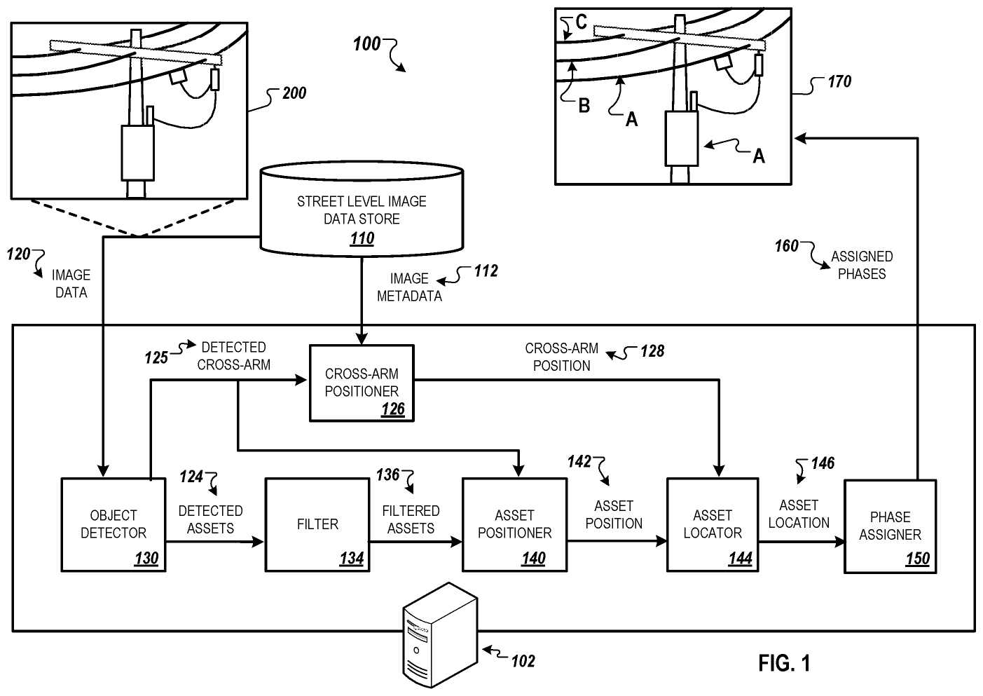

FIG. 1 is a diagram of an example system 100 for identifying electrical phases of electric grid wires using camera images. The system 100 includes a street level image data store 110 and a server system 102. The server system 102 may be hosted within a data center, which can be a distributed computing system having many computers in one or more locations. The server system 102 includes an object detector 130, a filter 134, a cross arm positioner 126, an asset positioner 140, an asset locator 144, and a phase assigner 150.

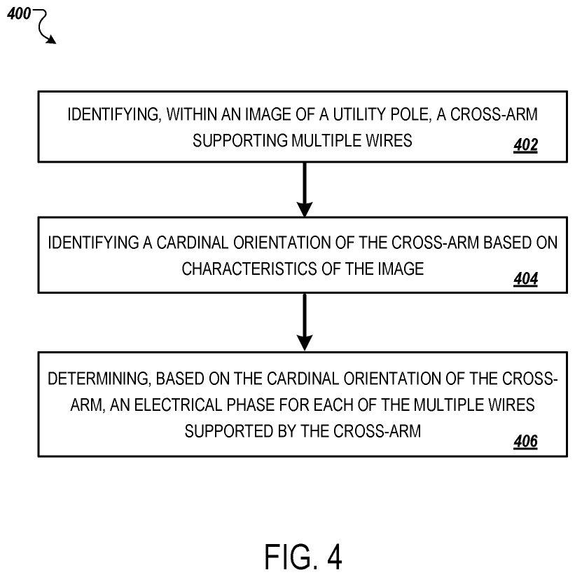

The system 100 can perform a process for identifying electrical phases of electric grid wires using camera images. FIG. 4 is a flow diagram of an example process 400 that can be performed by the system 100. Briefly, process 400 includes identifying, within an image of a utility pole, a cross arm supporting multiple wires (402), identifying a cardinal orientation of the cross arm based on characteristics of the image (404), and determining, based on the cardinal orientation of the cross arm, an electrical phase for each of the multiple wires supported by the cross arm (406). The process 400 can be performed by a computing system including one or more computers, such as the server system 102.

The components and modules of the server system 102 can each be provided as one or more computer executable software modules or hardware modules. That is, some or all of the functions of object detector 130, a filter 134, a cross arm positioner 126, an asset positioner 140, an asset locator 144, and phase assigner 150 can be provided as a block of computer code, which upon execution by a processor, causes the processor to perform functions described below. Some or all of the functions of the server system 102 can be implemented in electronic circuitry, e.g., by individual computer systems (e.g., servers), processors, microcontrollers, a field programmable gate array (FPGA), or an application specific integrated circuit (ASIC).

The server system 102 can obtain information indicating locations of utility poles, and can pull, from the street level image data store, images of the utility poles. Specifically, the server system 102 can obtain image data 120 from the street level image data store 110. The street level image data store 110 can include images captured by street level sensors. Street level sensors can include, for example, cameras mounted on vehicles. Street level sensors can include visible light cameras, infrared sensors, RADAR sensors, and LIDAR sensors.

The image data 120 can include visible light data, e.g., red-green-blue (RGB) data, collected by the street level sensors. The image data 120 can also include ranging data (e.g., LIDAR or RADAR data), hyperspectral data, multispectral data, and infrared data, collected by the street level sensors. In some examples, the image data 120 can include a combination of one or more types of images, e.g., visual light images with infrared illumination.

The street level image data store 110 can store images captured throughout a geographic region. The geographic region can include, for example, an area of hundreds of square meters, several kilometers, hundreds of kilometers, or thousands of kilometers. The geographic region can correspond to a location of an electrical distribution feeder or multiple feeders. In some cases, the geographic region can correspond to a location of a bulk power system within and throughout, e.g., a state, county, province, or country.

The street level image data store 110 can store metadata for the images in the data store. The metadata for an image can include, for example, data indicating a location of the camera that captured the image, an orientation of the camera that captured the image, a time that the image was captured, and a location of the utility pole in the image. The location of the camera and of the utility pole can be stored, for example, as GPS coordinate locations, e.g., latitudinal and longitudinal coordinate locations.

The orientation of the camera that captured the image can include, for example, a yaw, pitch, and roll of the camera. The yaw can represent rotation around a vertical axis with respect to a ground plane. For example, a yaw of zero can represent a camera pointing north, and a yaw of one hundred eighty can represent a camera pointing south. The pitch can represent rotation around a horizontal axis with respect to the ground plane. For example, a pitch of zero can represent a camera pointing downward toward the ground, and a pitch of one hundred can represent a camera pointing upwards toward the sky. The roll can represent rotation around a horizontal axis that is perpendicular to the pitch axis. In some examples, the orientation of the camera includes an elevation of the camera relative to the ground.

In some examples, the camera is mounted on a vehicle, and the orientation of the camera can be determined based on a direction of travel of the vehicle at the time when the image was captured. For example, the camera may have a fixed position and orientation relative to the vehicle, e.g., a yaw of ninety degrees relative to the direction of motion of the vehicle. Thus, based on the direction of travel of the vehicle, the yaw of the camera can be computed.

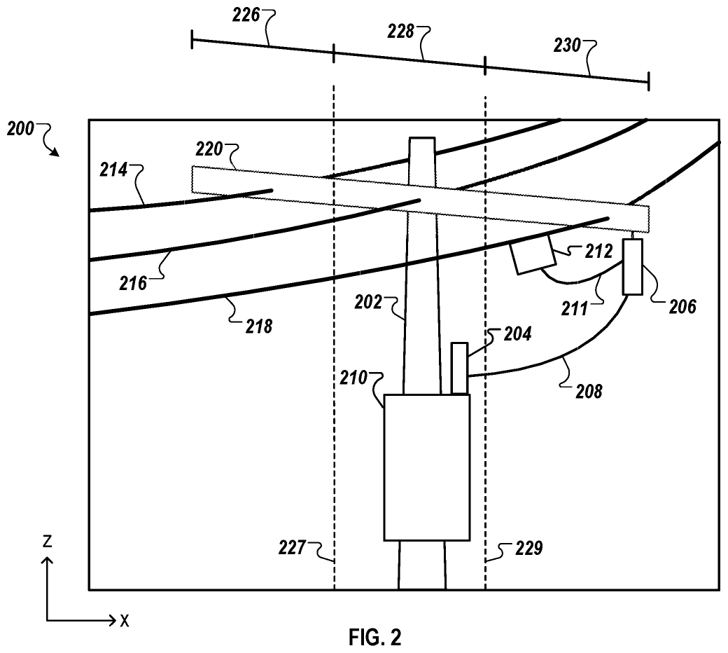

The server system 102 obtains image data 120 from the street level image data store 110. The image data 120 includes example image 200. The image 200 is shown in greater detail in FIG. 2. Referring to FIG. 2, the image 200 includes depictions of a utility pole 202, cross-arm 220, and grid wires 214, 216, and 218. With respect to the image 200, grid wire 214 is the left-most wire, grid wire 218 is the right-most wire, and grid wire 216 is the center wire.

The image 200 also includes depictions of a transformer 210, bushing 204, fuse 206, and stirrup 212. In the image 200, the fuse 206 is located nearest to the right-most wire, e.g., grid wire 218. The transformer 210 is connected to the grid wire 218 by the fuse 206 and the stirrup 212.

The image 200 shows an example configuration for a utility pole with a service transformer 210 that can provide power to loads such as houses in a residential area. There are three electrical grid wires 214, 216, 218 supported by the utility pole 202. The three wires are part of the primary electrical grid system. The primary electrical grid system carries electrical power from an electrical substation to the transformer 210. Wires connected from the transformer 210 to one or more loads can be considered part of the secondary electrical grid system. The three wires of the primary electrical grid system each carry an alternating current of the same frequency and voltage but with a phase difference of one third of a cycle between each. The three phases can be labeled as “A,” “B,” and “C” phases. One wire carries phase A, one wire carries phase B, and one wire carries phase C. The transformer 210 is only connected to one of the wires, e.g., the grid wire 218.

The transformer 210 includes a bushing 204. The bushing 204 is a hollow electrical insulator that allows an electrical conductor to pass safely through a conducting barrier such as the case of a transformer or circuit breaker without making electrical contact with the case.

The bushing 204 is connected to a cut-out fuse 206 by a first thin wire 208. The fuse 206 is a combination of a fuse and a switch that can be used in primary overhead feeder lines to protect distribution transformers from current surges and overloads. An overcurrent caused by a fault in the transformer or customer circuit will cause the fuse to melt, disconnecting the transformer from the line.

The fuse 206 connects, by a second thin wire 211, to a stirrup 212 that hangs from the grid wire 218. The stirrup 212 protects primary lines from arcing damage by allowing hot line clamp connections to be made without contacting the main line. The thin wires 208 and 211 may or may not be visible in the street level images of the utility pole 202.

Thus, the transformer 210 is connected to the primary electric grid wires through the fuse 206 and the stirrup 212. The fuse 206 and the stirrup 212 are therefore located nearest to the phase to which the transformer 210 is connected.

In some examples, street level imagery of utility poles can include depictions of other electrical grid assets. For example, in addition to transformers, fuses, wires, and stirrups, electric grid assets can include capacitors and switches located on or near the utility pole.

The process 400 includes identifying, within an image of a utility pole, a cross arm supporting multiple wires (402). For example, the object detector 130 can detect electric grid assets by performing image analysis on the image data 120. The object detector 130 can apply algorithms for object detection and object identification to the image data 120.

By applying object detection algorithms to the selected image data 120, the object detector 130 can identify or detect the existence of various electric grid assets. Grid assets can include, for example, transformers, capacitors, cross-arms, risers, insulators, reclosers, switch handles, switch control rods, voltage regulators, feeders, etc., that may be connected to, located on, or located near the utility pole. Thus, using image analysis, the object detector 130 can detect, classify, and identify objects in the image data 120, e.g., the grid assets in the example image 200.

In some examples, the object detector 130 can identify objects in the image data 120 using machine learning methods. The object detector 130 can include, for example, a convolutional neural network model that is trained to identify components of electric grids. The object detector 130 can be trained, for example, using large amounts of training data that includes training images of utility poles. The training images can be labeled with ground truth bounding boxes identifying the grid assets. The object detector 130 can be trained, using the labeled training images, to identify grid assets in images of utility poles.

When the object detector detects an object, the object detector can identify a bounding box around the image of the object in the image data 120. In some examples, the object detector 130 can apply one or more labels to each detected object. For example, the object detector 130 can generate a bounding box around transformer 104 and apply a label such as “transformer,” “single phase transformer,” “pole-mounted transformer,” etc.

The object detector 130 can identify, within the image data 120, a cross-arm supporting multiple wires. For example, the object detector 130 can identify the cross-arm 220 in the image 200 that supports the multiple grid wires 213, 214, and 218. The object detector 130 can output a detected cross-arm 125 to the cross-arm positioner 126 and the asset positioner 140. The detected cross-arm 125 can be represented, e.g., by a bounding box around the cross-arm 220 in the image 200. In some examples, the detected cross-arm 125 can be represented by a vector that represents the position and orientation of the cross-arm 220 in the image 200.

The object detector 130 can identify, within the image data 120, grid assets such as wires, transformers, fuses, and stirrups. The object detector 130 outputs the detected assets 124 to the filter 134. The detected assets 124 can be represented, e.g., by bounding boxes around each asset. The bounding boxes can be labeled by the type of identified asset, e.g., including labels such as “fuse,” “stirrup,” “transformer,” etc.

The process 400 includes identifying a cardinal orientation of the cross arm based on characteristics of the image (404). The cross-arm positioner 126 receives the detected cross-arm 125 from the object detector 130. The cross-arm positioner 126 also receives image metadata 112 from the street level image data store 110. The image metadata 112 includes characteristics of the image.

The image characteristics can include, for example, data indicating a location of the camera that captured the image 200, a time that the image 200 was captured, an orientation of the camera at the time the image 200 was captured, and a geographic location of the utility pole 202 in the image 200. In some examples, the metadata can include LIDAR data associated with the image 200. LIDAR data can include depth data for pixels of the image. For example, the LIDAR data can include, for each pixel, a distance between the camera and the object depicted by the pixel. Based on the detected cross-arm 125 and the image metadata 112, the cross-arm positioner 126 determines a cross-arm position 128.

In general, based on the location of the camera that captured the image of the utility pole, and the location of the utility pole, the cross-arm positioner 126 can determine a cardinal direction in which the camera was pointed. For example, the image characteristics can include a geographic location of the camera 310 when the camera 310 captures the image of the utility pole 322. The direction in which the camera was pointed can be estimated using a vector between the location of the camera and the location of the utility pole. Based on the cardinal direction in which the camera was pointed, and the position of the cross-arm in the image, the cross-arm positioner can determine the cardinal orientation of the cross-arm. The cardinal orientation can include, for example, a yaw orientation relative to a reference cardinal angle, e.g., north, or zero degrees.

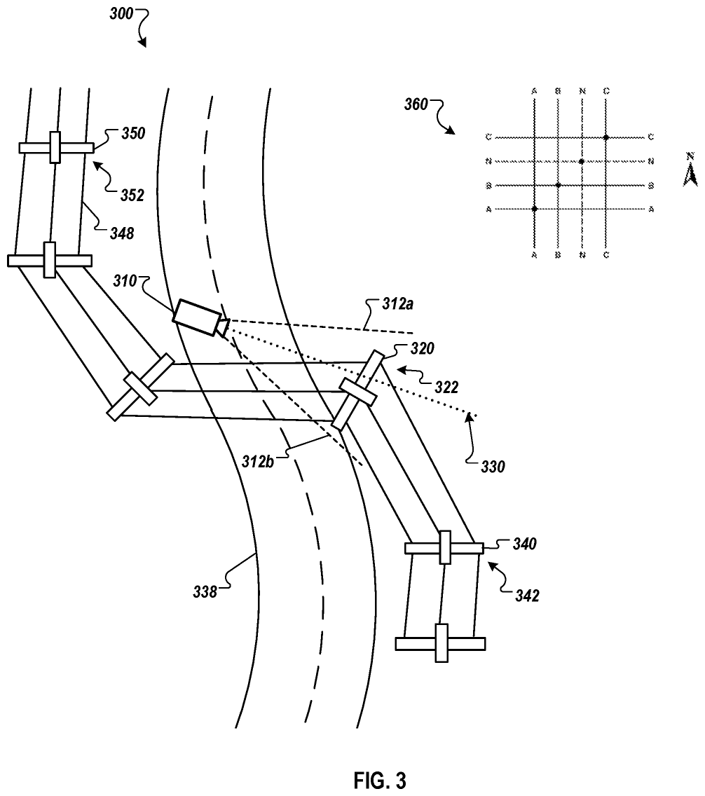

In some examples, the cross-arm positioner 126 can determine the cross-arm position 128 at least in part by determining an orientation of the cross-arm relative to an axis of a field of view (FOV) of the image. For example, referring to FIG. 3, which illustrates an example overhead view 300 of a portion of an electrical grid, a camera 310 captures an image of a utility pole 322. The camera 310 has a FOV that is defined in a horizontal plane by boundaries 312a and 312b. The FOV of the camera 310 has an FOV axis 330. The FOV axis 330 may have a cardinal orientation, e.g., of one hundred ten degrees relative to north. The cross-arm positioner 126 can determine the cardinal orientation of the FOV axis 330 of the camera 310 based on the characteristics of the image.

The cross-arm positioner 126 can estimate the cardinal orientation of the cross-arm 320 of the utility pole 322 based on an angular difference between the orientation of the cross-arm 320 relative to the FOV axis 330. For example, the cross-arm positioner 126 may determine an angular difference of eighty-five degrees between the FOV axis 330 and the orientation of the cross-arm 320. Thus, the cross-arm positioner 126 can estimate a cardinal orientation of the cross-arm 320 of approximately twenty-five degrees relative to north.

In some examples, the cross-arm positioner 126 can assign a cardinal direction to each end of the cross-arm. For example, the cross-arm positioner 126 may estimate a cardinal orientation of the cross-arm 320 of twenty-five degrees relative to north. Based on the cardinal orientation of the cross-arm 320 of twenty-five degrees, and the cardinal orientation of the FOV axis 330 of one hundred-ten degrees, the cross-arm positioner 126 can assign a cardinal direction of twenty-five degrees, or north-northeast, to the end of the cross-arm that appears to the left in the image captured by the camera 310. Similarly, the cross-arm positioner 126 can assign a reciprocal cardinal direction of two hundred five degrees, or south south-west, to the end of the cross-arm 320 that appears to the right in the image captured by the camera 310.

In some examples, the cross-arm positioner 126 can determine the orientation of the cross-arm relative to the FOV axis of the image at least in part by determining an aspect ratio of a bounding box generated around the cross-arm in the image. For example, the detected cross-arm 125 can include a bounding box around the cross-arm 220 in the image 200. The aspect ratio can include a ratio of length to height of the cross-arm in the image 200. In the image 200, a length dimension corresponds approximately to the x-direction, and a height dimension corresponds approximately to the z-direction.

The aspect ratio can indicate the orientation of the cross-arm relative to the FOV axis. A smaller aspect ratio can indicate that the image was captured from a perspective that is closer to an edge-wise perspective than to a broad side perspective. A smaller aspect ratio can therefore indicate a smaller, e.g., closer to parallel, angle between the FOV axis and the orientation of the cross-arm. In contrast, a larger aspect ratio can indicate that the image was captured from a perspective that is closer to a broad side perspective than to an edge-wise perspective. A larger aspect ratio can therefore indicate a larger, e.g., closer to orthogonal, angle between the FOV axis and the orientation of the cross-arm.

As an example, referring to FIG. 2, the aspect ratio is approximately twenty, e.g., the length of the cross-arm 220 in the image 200 is approximately twenty times the height of the cross-arm 220 in the image 200. The aspect ratio of approximately twenty indicates a relatively large angular difference between the FOV axis and the orientation of the cross-arm. For example, the angle between the FOV axis and the orientation of the cross-arm may be at least forty-five degrees, at least sixty degrees, or at least seventy degrees. A smaller aspect ratio, e.g., an aspect ratio of less than twenty or less than ten, may indicate a smaller angle between the FOV axis and the orientation of the cross-arm, e.g., an angular difference of at most forty-five degrees, at most thirty degrees, or at most twenty degrees.

In some examples, the cross-arm positioner 126 can determine the orientation of the cross-arm relative to the FOV axis at least in part by determining an angle of a bounding box generated around the cross-arm in the image. For example, the detected cross-arm 125 can include a bounding box around the cross-arm 220 in the image 200. The bounding box may be angled relative to a ground plane of the image, e.g., relative to the x-direction of the image 200.

The angle of the bounding box relative to the x-direction can indicate the orientation of the cross-arm relative to the FOV axis. A larger bounding box angle can indicate that the image was captured from a perspective that is closer to an edge-wise perspective than to a broad side perspective. A larger bounding box angle relative to the x-direction of the image can therefore indicate a smaller, e.g., closer to parallel, angle between the FOV axis and the orientation of the cross-arm. In contrast, a smaller bounding box angle can indicate that the image was captured from a perspective that is closer to a broad side perspective than to an edge-wise perspective. A smaller bounding box angle relative to the x-direction of the image can therefore indicate a larger, e.g., closer to orthogonal, angle between the FOV axis and the orientation of the cross-arm.

In some examples, the cross-arm positioner 126 can determine a cardinal orientation of a cross-arm based at least in part on LIDAR data associated with the image 200. The LIDAR data can include, for each pixel, an approximate distance between the camera and the object depicted by the pixel. Based on the cardinal orientation of the FOV axis, and the LIDAR data, the cross-arm positioner 126 can determine, for each pixel representing a portion of the cross-arm, a coordinate position indicated by latitude and longitude associated with the pixel. The cross-arm positioner 126 can then determine a cardinal orientation of the cross-arm based on the coordinate positions of the pixels representing portions of the cross-arm. For example, the cross-arm positioner 126 can determine a vector between a coordinate position of a first pixel at or near a first end of the cross-arm and a coordinate position of a second pixel at or near a second end of the cross-arm. The cardinal orientation of the cross-arm can be estimated to be the cardinal orientation of the vector.

In some examples, in addition to street level imagery, the cross-arm positioner 126 can obtain overhead imagery or map data. For example, the cross-arm positioner 126 can obtain a map of a geographic area where the utility pole is located. The cross-arm positioner 126 can identify a cardinal orientation of a street adjacent to the utility pole. Based on the cardinal orientation of the street adjacent to the utility pole, the cross-arm positioner 126 can estimate the cardinal orientation of the utility pole.

For example, referring to FIG. 3, utility pole 342 is adjacent to street 338. The cross-arm positioner 126 can analyze a map of the geographic area depicted in FIG. 3 to determine that the street 338 has a cardinal orientation of approximately zero degrees, e.g., the directions of travel along the street 338 are approximately north and south. Based on determining that the cardinal orientation of the street 338 is approximately zero degrees, the cross-arm positioner 126 can estimate the cardinal orientation of the adjacent utility pole 342. For example, the cross-arm positioner 126 can estimate that the cardinal orientation of the cross-arm 340 of the utility pole 342 is approximately orthogonal to the cardinal orientation of the street 338. Thus, the cross-arm positioner 126 can estimate an orientation of the cross-arm 340 to be approximately ninety degrees, with ends of the cross-arm 340 extending approximately to the east and to the west.

In some examples, using overhead imagery of a geographic area where the utility pole is located, the cross-arm positioner 126 can identify a cardinal orientation of electric grid wires that are connected to the utility pole. Based on the cardinal orientation of the electric grid wires that are connected to the utility pole, the cross-arm positioner 126 can estimate the cardinal orientation of the utility pole.

For example, referring to FIG. 3, utility pole 352 is connected to electric grid wire 348. The cross-arm positioner 126 can analyze overhead imagery of the geographic area depicted in FIG. 3 to determine that the electric grid wires 348 has a cardinal orientation of approximately zero degrees, e.g., approximately north and south. Based on determining that the cardinal orientation of the electric grid wire 348 is approximately zero degrees, the cross-arm positioner 126 can estimate the cardinal orientation of the connected utility pole 352. For example, the cross-arm positioner 126 can estimate that the cardinal orientation of the cross-arm 350 of the utility pole 352 is approximately orthogonal to the cardinal orientation of the electric grid wire 348. Thus, the cross-arm positioner 126 can estimate an orientation of the cross-arm 350 to be approximately ninety degrees, with ends of the cross-arm 340 extending approximately to the east and to the west.

In some implementations, the cross-arm positioner 126 can use two or more techniques for identifying the cardinal orientation of the cross-arm. The cross-arm 126 can use any combination of techniques described above in order to estimate the cross-arm position 128. For example, the cross-arm positioner 126 may estimate the cross-arm position 128 based on the aspect ratio of the cross-arm in the image, and may verify the cross-arm position 128 by analyzing map data indicating a cardinal orientation of a street that is adjacent to the associated utility pole. In another example, the cross-arm positioner 126 may estimate the cross-arm position based on the angle of the detected cross-arm 125 bounding box, and may verify the cross-arm position by analyzing overhead imagery indicating cardinal orientation of a grid wire connected to the associated utility pole.

The cross-arm positioner 126 outputs the cross-arm position 128 to the asset locator 144. The cross-arm position 128 can include, for example, a cardinal orientation of the cross-arm 220. In some examples, the cardinal orientation of the cross-arm 220 can include an angle of the cross-arm 220 with respect to a reference angle. In an example, the broad sides of a utility pole may face north, e.g., zero degrees, and south, e.g., one hundred eighty degrees, and the cross-arm may therefore extend from west, e.g., two hundred seventy degrees, to east, e.g., ninety degrees. The cross-arm positioner 126 may therefore output a cross-arm position 128 of ninety degrees or of two hundred seventy degrees. In some examples, the cross-arm position 128 can include a coordinate position of each end of the cross-arm. For example, the cross-arm position 128 can include a latitude and longitude of the left end of the cross-arm 220, and a latitude and longitude of the right end of the cross-arm 220.

The filter 134 receives the detected asset data 124 from the object detector 130. In some examples, the object detector 130 provides, to the filter 134, the image data 120 including labels for each detected asset. For example, the detected asset data 124 can include an image with bounding boxes labeled, e.g., “wire,” “transformer,” “fuse,” and “stirrup.” In some examples, the object detector 130 provides, to the filter 134, data indicating numbers of assets and types of assets detected in the image data 120. For example, the detected asset data 124 can include data indicating that an image depicts three grid wires supported by a cross-arm, one fuse, one stirrup, and one transformer.

The filter 134 filters out image data that does not satisfy criteria for phase identification. For each image, the filter 134 can determine whether the image satisfies the criteria. The criteria can include, for example, criteria related to the assets depicted in the image, criteria related to a number of transformers on a utility pole, criteria related to a number of electric grid wires supported by a cross-arm in the image, and criteria related to an aspect angle of the utility pole in the image. The filter 134 can filter out images that do not satisfy the criteria. Images that are filtered out by the filter 134 can be ignored or discarded. Images that satisfy the criteria, and are not filtered out, can be provided to the asset positioner 140.

In some examples, criteria can be related to the assets depicted in the image. For example, the filter 134 can be programmed to filter out images that do not include depictions of both a stirrup and a fuse. In some examples, the filter 134 can be programmed to filter out images that do not include depictions of at least one of a stirrup or a fuse. In some examples, the filter can be programmed to filter out images that include more than one stirrup or more than one fuse.

In some examples, criteria can be related to the number of transformers on a utility pole in the image. For example, the filter 134 can be programmed to filter out images that include no transformers. In some examples, the filter 134 can be programmed to filter out images that include more than one transformer. In some examples, the filter 134 can be programmed to filter out images that include more than two transformers.

In some examples, criteria can be related to the number of electric grid wires supported by the cross-arm of a utility pole in the image. For example, the filter 134 can be programmed to filter out images that include fewer than three phases supported by the cross-arm. In some examples, the filter 134 can be programmed to filter out images that include fewer than two phases supported by the cross-arm.

In some examples, criteria can be related to an aspect angle of the utility pole in the image. For example, some images may depict a utility pole from a broad side view or near broad side view, with the camera pointing in a direction approximately parallel to the direction of the electric grid wires and approximately parallel to a ground plane. A broad side view may depict a cross-arm extending across the image, and can enable identification of individual grid wires and assets that are located on or near the cross-arm. Other images may depict a utility pole from an edge view or near-edge view, with the camera pointing in a direction approximately perpendicular to the direction of the electric grid wires and approximately parallel to the ground plane. An edge view may depict an aspect of a cross-arm that does not allow for identification of individual grid wires and assets. In some examples, the filter 134 can be programmed to filter out images that depict the utility pole at an angle that precludes accurate identification of individual electric grid wires and assets. For example, the filter 134 can include a minimum length of the depiction of the cross-arm, e.g., as measured in pixels. The filter 134 can filter out images in which the length of the cross-arm in the image is less than the minimum length.

The filter 134 outputs filtered asset data 136 to the asset positioner 140. The filtered asset data 136 can include, for example, labeled bounding boxes identifying assets depicted in images that were not filtered out by the filter 134.

The asset positioner 140 receives the detected cross-arm 125 and the filtered asset data 136. For each asset, the asset positioner 140 determines asset position data 142 for an asset from the filtered asset data 136. For example, asset position data 142 can indicate an asset's position relative to the cross-arm. For example, the filtered asset data 136 can include a labeled bounding box identifying the fuse 206 depicted in the image 200. The asset positioner 140 can determine a position of the fuse 206 relative to the cross-arm 220.

In some examples, to determine a position of the fuse 206 relative to the cross-arm 220, the asset positioner 140 can divide the depiction of the cross-arm 220 into three sections, each section corresponding to a grid wire that is supported by the section of the cross-arm. The three sections can be, for example, three equal sections divided along the length of the cross-arm 220. The length of the cross-arm 220 can be defined as a length of the cross-arm that is parallel, or approximately parallel, to the ground plane.

For example, referring to FIG. 2, the depiction of cross-arm 220 can be divided into three sections 226, 228, 230. The three sections can be defined by boundaries 227, 229. For example, section 226 of the cross-arm 220 is a portion of the cross-arm that is to the left of boundary 227 in the image 200. Section 228 of the cross-arm 220 is a portion of the cross-arm 220 that is in between the boundary 227 and the boundary 229. Section 230 is a portion of the cross-arm that is to the right of boundary 229 in the image 200. The sections 226, 228, and 230 can be labeled “left,” “center,” and “right,” respectively.

After dividing the depiction of the cross-arm 220 into three sections, the asset positioner 140 can then determine the section to which the asset is located nearest. For example, the asset positioner 140 can determine that a bounding box for the fuse 206 is located nearest to the right-most section of the cross-arm, e.g., section 230.

In some examples, the asset positioner 140 can use machine learning techniques to determine whether the fuse 206 and the stirrup 212 are located left, right, or center relative to the cross-arm 220. For example, the asset positioner 140 can include a neural network model that is trained using labeled training images of utility poles including at least one of fuse or a stirrup. The asset positioner 140 can be trained using a supervised training process to identify the position of fuses and stirrups relative to cross-arms in the training images.

The asset positioner 140 provides the asset position data 142 to the asset locator 144. The asset locator 144 also receives, from the cross-arm positioner 126, the cross-arm position 128. Based on the cross-arm position 128 and the asset position data 142, the asset locator 144 determines an asset location 146.

As an example, the asset locator 144 may receive, from the asset positioner 140, asset position data 142 indicating that the fuse 206, the stirrup 212, or both, are located nearest to the right-most section of the cross-arm 220. The asset locator 144 may also receive, from the cross-arm positioner 126, a cardinal orientation of the cross-arm 220 indicating that the left-most end of the cross-arm 220 extends to the east, and the right-most end of the cross-arm extends to the west.

Based on the asset position data 142 of the fuse 206, the stirrup 212, or both, being located nearest to the right-most section of the cross-arm 220, and the cross-arm position 128 of the right-most end of the cross-arm extending to the west, the asset locator 144 can output an asset location 146 indicating that the fuse 206, the stirrup 212, or both, are located on the western side of the cross-arm 220. Based on the fuse 206, the stirrup 212, or both, being located on the western side of the cross-arm 220, the asset locator 144 can also output an asset location 146 indicating that the transformer 210 is connected to the west-most grid wire that is supported by the cross-arm 220.

The asset locator 144 can also receive, from the asset positioner 140, asset position data 142 indicating that grid wire 214 is located nearest to the left-most section of the cross-arm 220, that grid wire 216 is located nearest to the center section of the cross-arm 220, and that grid wire 218 is located nearest to the right-most section of the cross-arm 220.

The asset locator 144 can identify, for each grid wire, a respective position of the grid wire on the cross-arm 220. The asset locator 144 can output asset locations 146 for each of the grid wires 214, 215, 218. The asset locations 146 can indicate that the grid wire 214 is located nearest to the eastern side of the cross-arm 220, that the grid wire 218 is located nearest to the western side of the cross-arm 220, and that the grid wire 216 is located between the eastern and western sides of the cross-arm 220.

The process 400 includes determining, based on the cardinal orientation of the cross arm, an electrical phase for each of the multiple wires supported by the cross arm (406). For example, the phase assigner 150 can determine, for each wire, a respective electrical phase of the wire based on the respective position of the wire on the cross-arm and the cardinal orientation of the cross-arm. Based on the determination that the grid wire 214 is located nearest to the eastern side of the cross-arm 220, that the grid wire 218 is located nearest to the western side of the cross-arm 220, and that the grid wire 216 is located between the eastern and western sides of the cross-arm 220, the phase assigner 150 can determine an electrical phase for each of the grid wires 214, 216, 218.

In some examples, the phase assigner 150 can determine the respective electrical phase of each wire by comparing the respective position of the wire on the cross-arm and the cardinal orientation of the cross-arm to a wire phasing diagram or map. In some examples, the phase assigner 150 can use a phasing standard such as a utility phasing standard to determine an electrical phase for each of the grid wires, e.g., grid wires 214, 216, and 218. A utility phasing standard describes how the A, B, C phases are mounted on utility poles based on the cardinal orientation of the wires, which generally run perpendicular to the cross-arms. For example, most utilities build grids such that the southern or western phase on a cross-arm is phase A, the middle phase is B, and the northern or eastern phase is C.

An example phasing standard 360 is shown in FIG. 3. The phasing standard 360 shows that for electric grid wires extending approximately in the north-south directions, a west-most wire is assigned to phase A, a center wire is assigned to phase B, and an east-most wire is assigned to phase C. For electric grid wires extending approximately in the east-west directions, a south-most wire is assigned to phase A, a center wire is assigned to phase B, and a north-most wire is assigned to phase C. The phasing standard also shows that a neutral wire may be positioned between phases B and C. Phasing standards may vary according to government and utility standards. The phase assigner 150 can be programmed to apply a phasing standard appropriate for the location of the utility pole.

In some examples, a utility pole can include more than one cross-arm. For example, a utility pole can include a first cross-arm supporting wires extending in a north-south direction, and a second cross-arm supporting wires extending in an east-west direction. The first cross-arm and the second cross-arm can be positioned on the utility pole such that the first cross-arm and the second cross-arm are spaced apart in a vertical direction. The north-south wires can be connected to the east-west wires, e.g., by vertically extending wires. The vertically extending wires can connect respective phases of the wires, e.g., by vertically connecting phase A of the north-south grid wires to phase A of the east-west grid wires. This can allow for phasing standards to be upheld at utility poles where turns or intersections occur between grid wires extending in different directions.

The utility phasing standard can enable the phase assigner 150 to translate a cardinal position of an asset, such as a fuse or stirrup, to a phase of the electric grid. For example, based on determining that the fuse 206, stirrup 212, or both, are connected to the west-most grid wire, the phase assigner 150 can determine that the fuse and/or stirrup, and hence the transformer, are connected to the A phase.

In some examples, the phase assigner 150 can assign a phase to a fuse, stirrup, transformer, or any of these, using machine learning methods. The phase assigner 150 can include, for example, a convolutional neural network model that is trained to classify a transformer as being connected to a left grid wire, a middle grid wire, a right grid wire, or an unknown grid wire in an image. The phase assigner 150 can be trained, for example, using large amounts of training data that includes labeled training images of utility poles including transformers. The training images can be labeled with a ground truth classification of the grid wire that is connected to the transformer, and a supervised training process can be used to train the phase assigner 150 to identify the grid wire to which the transformer is connected in the training images. To perform inference, the trained phase assigner 150 can receive, as input, an image of a utility pole including grid wires and a transformer, and can output an indication of a predicted grid wire that is connected to the transformer.

The phase assigner 150 outputs assigned phases 160. In some examples, the phase assigner 150 can output assigned phases 160 for each of the electric grid wires supported by the cross-arm 220 in the image 200. For example, the phase assigner 150 can output a labeled image assigning the right-most grid wire to phase A, the center grid wire to phase B, and the left-most grid wire to phase C. The phase assigner 150 can also output data indicating that transformer 210, and loads supplied by the transformer 210, are on phase A.

In some examples, the assigned phases 160 can be stored in association with a database of electric loads. For example, a database may store data indicating loads that are supplied by the electric grid. The phase assigner 150 can assign phase A to the loads in the database that are supplied by the transformer 210.

The phase assignments can be used to improve load balancing in electric grid planning. For example, based on the assigned phases 160, new loads can be added to a phase that has a lower load than other phases. In some examples, the assigned phases 160 can be incorporated into a model of the electric grid. The model can be used for accurate modeling and simulation of electric grid operations.

Implementations of the subject matter and the functional operations described in this specification can be implemented in digital electronic circuitry, in tangibly-implemented computer software or firmware, in computer hardware, including the structures disclosed in this specification and their structural equivalents, or in combinations of one or more of them. Implementations of the subject matter described in this specification can be implemented as one or more computer programs, i.e., one or more modules of computer program instructions encoded on a tangible non-transitory program carrier for execution by, or to control the operation of, data processing apparatus. The computer storage medium can be a machine-readable storage device, a machine-readable storage substrate, a random or serial access memory device, or a combination of one or more of them.

The term “data processing apparatus” refers to data processing hardware and encompasses all kinds of apparatus, devices, and machines for processing data, including, by way of example, a programmable processor, a computer, or multiple processors or computers. The apparatus can also be or further include special purpose logic circuitry, e.g., a central processing unit (CPU), a FPGA (field programmable gate array), or an ASIC (application-specific integrated circuit). In some implementations, the data processing apparatus and/or special purpose logic circuitry may be hardware-based and/or software-based. The apparatus can optionally include code that creates an execution environment for computer programs, e.g., code that constitutes processor firmware, a protocol stack, a database management system, an operating system, or a combination of one or more of them. The present disclosure contemplates the use of data processing apparatuses with or without conventional operating systems, for example Linux, UNIX, Windows, Mac OS, Android, iOS or any other suitable conventional operating system.

A computer program, which may also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, subroutine, or other unit suitable for use in a computing environment. A computer program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a communication network. While portions of the programs illustrated in the various figures are shown as individual modules that implement the various features and functionality through various objects, methods, or other processes, the programs may instead include a number of sub-modules, third party services, components, libraries, and such, as appropriate. Conversely, the features and functionality of various components can be combined into single components as appropriate.

The processes and logic flows described in this specification can be performed by one or more programmable computers executing one or more computer programs to perform functions by operating on input data and generating output. The processes and logic flows can also be performed by, and apparatus can also be implemented as, special purpose logic circuitry, e.g., a central processing unit (CPU), a FPGA (field programmable gate array), or an ASIC (application-specific integrated circuit).

Computers suitable for the execution of a computer program include, by way of example, can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer-readable media (transitory or non-transitory, as appropriate) suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The memory may store various objects or data, including caches, classes, frameworks, applications, backup data, jobs, web pages, web page templates, database tables, repositories storing business and/or dynamic information, and any other appropriate information including any parameters, variables, algorithms, instructions, rules, constraints, or references thereto. Additionally, the memory may include any other appropriate data, such as logs, policies, security or access data, reporting files, as well as others. The processor and the memory can be supplemented by, or incorporated in, special purpose logic circuitry.

To provide for interaction with a user, implementations of the subject matter described in this specification can be implemented on a computer having a display device, e.g., a CRT (cathode ray tube), LCD (liquid crystal display), or plasma monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

The term “graphical user interface,” or GUI, may be used in the singular or the plural to describe one or more graphical user interfaces and each of the displays of a particular graphical user interface. Therefore, a GUI may represent any graphical user interface, including but not limited to, a web browser, a touch screen, or a command line interface (CLI) that processes information and efficiently presents the information results to the user. In general, a GUI may include a plurality of user interface (UI) elements, some or all associated with a web browser, such as interactive fields, pull-down lists, and buttons operable by the business suite user. These and other UI elements may be related to or represent the functions of the web browser.

Implementations of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN), a wide area network (WAN), e.g., the Internet, and a wireless local area network (WLAN).

The computing system can include clients and servers. A client and server are generally remote from each other and typically interact through a communication network. The relationship of client and server arises by virtue of computer programs running on the respective computers and having a client-server relationship to each other.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of sub-combinations.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be helpful. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations, alterations, and permutations of the described implementations are within the scope of the following claims as will be apparent to those skilled in the art. For example, the actions recited in the claims can be performed in a different order and still achieve desirable results.

Accordingly, the above description of example implementations does not define or constrain this disclosure. Other changes, substitutions, and alterations are also possible without departing from the spirit and scope of this disclosure.

What is claimed is:

1. A computer-implemented electrical phase detection method executed by one or more processors, the method comprising:
identifying, within an image of a utility pole, a cross-arm supporting multiple wires;
identifying a cardinal orientation of the cross-arm based on characteristics of the image; and
determining, based on the cardinal orientation of the cross-arm, an electrical phase for each of the multiple wires supported by the cross-arm.

2. The method of claim 1, wherein identifying the cross-arm supporting multiple wires comprises:
processing the image with an object detection model to obtain a corresponding output of the object detection model, the corresponding output of the object detection model including a bounding box around the cross-arm in the image.

3. The method of claim 1, wherein identifying the cardinal orientation of the cross-arm comprises:
determining an orientation of the cross-arm relative to an axis of a field of view of the image;
determining, based on the characteristics of the image, a cardinal orientation of the axis of the field of view; and
estimating the cardinal orientation of the cross-arm based on an angular difference between the orientation of the cross-arm relative to the axis of a field of view and the cardinal orientation of the axis of the field of view.

4. The method of claim 3, wherein determining the orientation of the cross-arm relative to the axis of the field of view of the image comprises determining an aspect ratio of a bounding box around the cross-arm in the image, the aspect ratio indicating the orientation of the cross-arm relative to the axis of a field of view.

5. The method of claim 1, wherein identifying the cardinal orientation of the cross-arm comprises:
identifying a cardinal orientation of a street adjacent to the utility pole within a map of a geographic location of the utility pole; and
determining the cardinal orientation of the cross-arm based on the cardinal orientation of the street.

6. The method of claim 5, wherein the cardinal orientation of the cross-arm is approximately orthogonal to the cardinal orientation of the street.

7. The method of claim 1, wherein determining the electrical phase for each of the multiple wires comprises:
identifying, for each wire, a respective position of the wire on the cross-arm; and
determining, for each wire, a respective electrical phase of the wire based on the respective position of the wire on the cross-arm and the cardinal orientation of the cross-arm.

8. The method of claim 7, wherein the respective electrical phase of the wire is determined based on the respective position of the wire on the cross-arm and the cardinal orientation of the cross-arm as compared with a wire phasing diagram.

9. The method of claim 7, wherein the respective electrical phase of the wire is determined based on the respective position of the wire on the cross-arm and the cardinal orientation of the cross-arm as compared with a wire phasing map.

10. The method of claim 1, further comprising:
identifying, within the image, a transformer and a stirrup; and
determining a particular electrical phase to which the transformer is connected by identifying a particular wire of the multiple wires that is nearest to the stirrup.

11. The method of claim 1, wherein the image of the utility pole includes a depiction of an electric grid asset, the electric grid asset comprising one of a capacitor, a fuse, a transformer, or a switch.

12. The method of claim 11, further comprising:
identifying, within the image, the electric grid asset; and
determining a particular electrical phase to which the electric grid asset is connected by identifying, within the image, a particular wire of the multiple wires that is connected to the electric grid asset.

13. The method of claim 11, comprising:
determining a particular electrical phase to which the electric grid asset is connected, the determining comprising:
processing the image with a convolutional neural network model to obtain a corresponding output of the convolutional neural network model, the corresponding output of the convolutional neural network model including a classification of the electric grid asset as being connected to a particular wire of the multiple wires.

14. The method of claim 1, wherein the image includes at least one of visible light imagery, infrared imagery, hyperspectral imagery, multispectral imagery, RADAR imagery, or LIDAR imagery.

15. The method of claim 1, wherein the image of the utility pole comprises a camera image captured by a camera positioned at street level.

16. The method of claim 1, wherein the characteristics of the image comprise one or more of: metadata indicating an orientation of a camera at a time the image was captured, LIDAR data associated with the image, or geographic location data associated with the image.

17. A system comprising one or more computers and one or more storage devices on which are stored instructions that are operable, when executed by the one or more computers, to cause the one or more computers to perform operations comprising:
identifying, within an image of a utility pole, a cross-arm supporting multiple wires;
identifying a cardinal orientation of the cross-arm based on characteristics of the image; and
determining, based on the cardinal orientation of the cross-arm, an electrical phase for each of the multiple wires supported by the cross-arm.

18. The system of claim 17, wherein identifying the cross-arm supporting multiple wires comprises:
processing the image with an object detection model to obtain a corresponding output of the object detection model, the corresponding output of the object detection model including a bounding box around the cross-arm in the image.

19. The system of claim 17, wherein identifying the cardinal orientation of the cross-arm comprises:
determining an orientation of the cross-arm relative to an axis of a field of view of the image;
determining, based on the characteristics of the image, a cardinal orientation of the axis of the field of view; and
estimating the cardinal orientation of the cross-arm based on an angular difference between the orientation of the cross-arm relative to the axis of a field of view and the cardinal orientation of the axis of the field of view.

20. A non-transitory computer storage medium encoded with instructions that, when executed by one or more computers, cause the one or more computers to perform operations comprising:
identifying, within an image of a utility pole, a cross-arm supporting multiple wires;
identifying a cardinal orientation of the cross-arm based on characteristics of the image; and
determining, based on the cardinal orientation of the cross-arm, an electrical phase for each of the multiple wires supported by the cross-arm.
